(19) United States
(12) Patent Application Publication
(10) Pub. No.: US 2021/0203422 A1
(43) Pub. Date: Jul. 1, 2021

(54) LOCATION OF A SOURCE OF PASSIVE INTERMODULATION WITHIN AN ANTENNA ARRAY

(71) Applicant: AceAxis Limited, Harlow (GB)

(72) Inventors: Simon GALE, Harlow (GB); David Damian Nicholas BEVAN, Harlow (GB)

(21) Appl. No.: 17/127,478

(22) Filed: Dec. 18, 2020

Related U.S. Application Data
(63) Continuation of application No. PCT/GB2019/051868, filed on Jul. 1, 2019.

(30) Foreign Application Priority Data
Jun. 29, 2018 (GB) 1810769.8

(51) Int. Cl. H04B 17/00; H04B 1/525; G01R 23/20; H04B 1/10

(52) U.S. Cl. CPC H04B 17/0085; H04B 1/1027; G01R 23/20; H04B 1/525

(57) ABSTRACT

A location of at least one PIM source within an antenna array assembly is determined by applying an excitation waveform to a connection port, setting a multi-element phase shifter to a first state to apply a respective phase shift to respective paths, and making a first measurement of at least the phase of a PIM product emitted from the connection port. The multi-element phase shifter is then set to a succession of further states and further such measurements are made for each of the further states. From the first and further measurements a dependence is determined of at least the phase of the PIM product on the state of the multi-element phase shifter. The determined dependence is compared with a plurality of predetermined dependences, each predetermined dependence being for a PIM source located in a respective path between the multi-element phase shifter and a respective sub-array to determine the location within the antenna array assembly of the at least one PIM source.

### CROSS-REFERENCE TO RELATED APPLICATIONS

This application is a continuation of International Application No. PCT/GB2019/051868, filed Jul. 1, 2019, which claims priority to GB Application No. 1810769.8, filed Jun. 29, 2018, under 35 U.S.C. § 119(a). Each of the above-referenced patent applications is incorporated by reference in its entirety.

### BACKGROUND

### Technical Field

The present invention relates generally to methods and apparatus for location of a source of passive intermodulation (PIM) within an antenna array assembly.

### Background

Passive intermodulation (PIM) may be generated in a wireless network when one or more signals are transmitted along a signal path including a passive component having a non-linear transmission characteristic. PIM products typically differ in frequency from the signal or signals from which they were generated, and may potentially cause interference to other signals. The generation of non-linear products is becoming a problem of increasing importance in modern wireless communication systems, and in particular cellular wireless systems, since the radio frequency spectrum available has been steadily expanded as additional bands have become available, and the pattern of allocation of uplink and downlink bands within the available spectrum for use by various cellular systems, such systems using GERAN (GSM EDGE Radio Access Network), UTRAN (UMTS Terrestrial Radio Access Network) and E-UTRAN (Evolved UMTS Terrestrial Radio Access Network) radio access networks, and by various operators, is complex and territorially dependent. Non-linear products generated from transmitted carriers in one or more downlink bands may fall as interference within an uplink band in which signals are received at the base station. This interference may limit the capacity of the radio system, and so it is important to minimise the level of PIM generated in a wireless system. Antennas and their feed networks may exhibit a non-linear transmission characteristic to some degree which may generate PIM, for example due to an oxide layer at a metal to metal contact, or a poor solder joint during manufacture. An antenna array may be provided, for example base station antennas typically comprise a vertical array of antenna elements fed by a feed network to produce a narrow beam in elevation and a broader beam in azimuth. The elevation angle of the beam is typically adjusted on installation of the antenna and may be further adjusted in use. Typically, the beam is given a certain angle of down-tilt from the horizontal, to limit interference to the areas of coverage of other base stations. In order to facilitate the adjustment of the tilt angle, a Remote Electrical Tilt (RET) facility may be provide for an antenna array, by which the relative transmission and/or reception phase of antenna elements or groups of antenna elements (sub-arrays) may be adjusted, by providing a incremental phase shift across the array, which has the effect of tilting the beam angle. Typically, an antenna array assembly may be provided with a controllable multi-element phase shifter, which may be an electro-mechanical device comprising signal splitters/combiners and sliding capacitive contacts, which may adjust the phase of a plurality of transmission paths by a change of path length. The controllable multi-element phase shifter may be set by use of an electric motor.

There are many locations within an antenna array assembly comprising a controllable multi-element phase shifter at which PIM may be generated. It may be desired to locate a PIM source within the antenna array assembly for diagnosis of a fault condition, or as a factory test, for example. Existing methods of locating PIM in a signal path involve using a swept frequency excitation and deriving a distance between the PIM source and the receiver from a delay value derived from the phase gradient of the received PIM. This technique may be useful to detect sources of PIM in the wireless propagation path, such as a PIM source on a rusty part of an antenna tower, but such techniques may not be able to distinguish between PIM sources in a branched structure such as an antenna array assembly in which a single connection port may be connected to several branches of the antenna array, each branch for example being a feed to a sub-array, and each branch being provided with a respective phase shift by a controllable multi-element phase shifter.

It is an object of the invention to address at least some of the limitations of the prior art systems.

### SUMMARY

In accordance with a first aspect of the present invention there is provided a method of identifying a location of at least one PIM (passive intermodulation) source within an antenna array assembly comprising a plurality of sub-arrays, a connection port, and a controllable multi-element phase shifter configured to apply a respective phase shift to a respective path between the connection port and each sub-array, the method comprising:
applying an excitation waveform to the connection port;
setting the multi-element phase shifter to a first state to apply a respective phase shift to each of the respective paths;
making a first measurement of at least the phase of a PIM product emitted from the connection port in response to the excitation waveform;
setting the multi-element phase shifter to a succession of further states, the respective phase shift applied to each of the respective paths being dependent on the state, and making a further measurement of at least the phase of the PIM product emitted from the connection port for each of the further states;
determining from the first and further measurements a dependence of at least the phase of the PIM product on the state of the multi-element phase shifter;
comparing the determined dependence of at least the phase of the PIM product on the state of the multi-element phase shifter with a plurality of predetermined dependences of at least the phase of the PIM product on the state of the multi-element phase shifter, each predetermined dependence being for a PIM source located in a respective path between the multi-element phase shifter and a respective sub-array, including the respective sub-array; and
determining the location within the antenna array assembly of the at least one PIM source in dependence on said comparing.

This allows identification of the signal path within the antenna array assembly in which the PIM source is likely to be located.

In an embodiment of the invention, the first and the further measurements are of the amplitude and phase of the PIM product, and the method comprises determining from the first and further measurements a dependence of the amplitude and phase of the PIM product on the state of the multi-element phase shifter, and said comparing comprises:
comparing the determined dependence of the amplitude and phase of the PIM product on the state of the multi-element phase shifter with a plurality of predetermined dependences of the amplitude and phase of the PIM product on the state of the multi-element phase shifter, each predetermined dependence being for a PIM source located in a respective path between the multi-element phase shifter and a respective sub-array, including the respective sub-array.

This may allow more accurate identification of the path in which the PIM source is likely to be located by taking into account amplitude as well as phase variation, which may result for imperfect impedance matching in the antenna array causing reflections.

In an embodiment of the invention, said comparing comprises a cross-correlation

This provides an efficient method of identifying which path a PIM source is likely to be located on, in particular in the case of a single PIM source.

In an embodiment of the invention, said comparing comprises a Linear Least Squares process, which may comprise identifying the location of one or more PIM sources by solution of Ax=b,
where:
A is a matrix of a plurality of predetermined dependences of the amplitude and phase of the PIM product on the state of the multi-element phase shifter, for PIM sources in different paths;
b is a column vector representing the determined dependence of the measured amplitude and phase of the PIM product on the state of the multi-element phase shifter; and
x is a vector indicating the probability of PIM being located in each path.

This provides an efficient method of identifying which path or paths a PIM source or sources are likely to be located on, particularly in the case of more than one PIM source.

In embodiments of the invention, the controllable multi-element phase shifter is a device for applying a Remote Electrical Tilt (RET), which may comprise a plurality of power dividers and a plurality of controllable phase shifting elements, and each sub-array may comprise one or more antenna elements for radiation and/or reception.

In an embodiment of the invention, the excitation waveform comprises a first and a second signal, wherein at least the first signal is a continuous wave (CW) signal.

This provides a convenient way of implementing an excitation waveform.

In an embodiment of the invention, the second signal is a continuous wave (CW) signal.

This provides a convenient way of implementing an excitation waveform for generating PIM of an expected frequency.

In an embodiment of the invention, the second signal is a modulated signal. The second signal may be modulated with a noise-like waveform having a bandwidth in the range 10 MHz to 40 MHz.

This provides a convenient way of implementing an excitation waveform for generating PIM, which may provide improved resilience to phase distortion from reflections and element mutual coupling, and may facilitate delay measurements to determine range to a PIM source or sources as well as path.

In an embodiment of the invention, the method comprises:
determining a delay of the PIM product by correlation of measured PIM with a replica of the PIM product; and
determining the location of the at least one PIM source in dependence on the determined delay in combination with a path determined by said comparing.

This allows more precise determination of which part or parts of the antenna array assembly is the location of a PIM source, by allowing a location to be determined in terms of distance along a path in addition to identifying on which signal path within the antenna array assembly the PIM source or sources are located.

In an embodiment of the invention, the plurality of predetermined dependences of at least the phase of the PIM product on the state of the multi-element phase shifter include effects of mutual coupling between sub-arrays.

This may allow more accurate identification of which path is causing PIM in the presence of mutual coupling.

In an embodiment of the invention, the plurality of predetermined dependences of at least the phase of the PIM product on the state of the multi-element phase shifter include effects of reflections between the phase shifter and the sub-arrays.

This may allow more accurate identification of which path is causing PIM in the presence of reflections within the antenna array assembly.

In an embodiment of the invention, the plurality of predetermined dependences of at least the phase of the PIM product on the state of the multi-element phase shifter includes dependencies for reflective paths.

This may allow the identification of reflective paths in addition to direct paths which may further assist in identifying a location or locations of sources of PIM.

In an embodiment of the invention, each state of the phase shifter represents a tilt angle for the antenna array.

In accordance with a second aspect of the invention, there is provided test apparatus for identifying a location of at least one PIM (passive intermodulation) source within an antenna array assembly comprising a plurality of sub-arrays, a connection port, and a controllable multi-element phase shifter configured to apply a respective phase shift to a respective path between the connection port and each sub-array, the test apparatus comprising:
a signal generator configured to generate an excitation waveform for application to the connection port;
a receiver configured to receive a PIM product emitted from the connection port in response to the excitation waveform; and
a circuit comprising a processor configured to:
set the multi-element phase shifter to a first state to apply a respective phase shift to each of the respective paths;
make a first measurement of at least the phase of a PIM product emitted from the connection port in response to the excitation waveform;
set the multi-element phase shifter to a succession of further states, the respective phase shift applied to each of the respective paths being dependent on the state, and making a further measurement of at least the phase of the PIM product emitted from the connection port for each of the further states;
determine from the first and further measurements a dependence of at least the phase of the PIM product on the state of the multi-element phase shifter; and
compare the determined dependence of at least the phase of the PIM product on the state of the multi-element phase shifter with a plurality of predetermined dependences of at least the phase of the PIM product on the state of the multi-element phase shifter, each predetermined dependence being for a PIM source located in a respective path between the multi-element phase shifter and a respective sub-array, including the respective sub-array; and
determine the location within the antenna array assembly of the at least one PIM source in dependence on said comparing.

Further features and advantages of the invention will be apparent from the following description of preferred embodiments of the invention, which are given by way of example only.

### BRIEF DESCRIPTION OF THE DRAWINGS

FIG. 1 is a schematic diagram showing test equipment in an embodiment of the invention connected to a device under test (DUT) which is an antenna array assembly;

FIG. 2 shows examples of a plurality of predetermined dependences of at least the phase of the PIM product on the state (tilt angle) of the multi-element phase shifter, each predetermined dependence being for a PIM source located in a respective path between the multi-element phase shifter and a respective sub-array;

FIG. 3 is a flow chart showing a method of identifying a location of at least one PIM (passive intermodulation) source within an antenna array assembly in an embodiment of the invention;

FIG. 4 shows an example of an excitation waveform in the frequency domain in an embodiment of the invention;

FIG. 5 shows an example of the implementation of the connection of the excitation waveform generator and the PIM receiver to the connection port of the antenna array assembly under test in an embodiment of the invention;

FIG. 6 illustrates a grid for determining a location of a PIM source within an antenna array assembly using a combination of delay and path, i.e branch, location;

FIG. 7 shows an example of a reflective signal path within an antenna array assembly;

FIG. 8 is a flow chart showing a method of identifying and displaying a location of at least one PIM (passive intermodulation) source within a device under test (DUT) in an embodiment of the invention; and

FIG. 9 is a flow diagram illustrating a process flow for analytics of PIM location.

### DETAILED DESCRIPTION

By way of example, embodiments of the invention will now be described in the context of identifying a location of at least one PIM (passive intermodulation) source in an antenna array assembly for use in in cellular wireless networks such as GSM, 3G (UMTS) and LTE (Long Term Evolution) networks comprising GERAN, UTRAN and/or E-UTRAN radio access networks, but it will be understood that embodiments of the invention may relate to other types of branched radio frequency device and to other types of radio access network, and that embodiments of the invention are not restricted to cellular wireless systems or to base station antennas.

In a cellular wireless network, PIM may be generated in a component due to a passive non-linear characteristic, albeit a relatively weak non-linear characteristic. The non-linear characteristic may be caused by an oxide layer between metallic parts, for example in an antenna array assembly at a base station. The antenna array assembly may be impinged upon by the downlink transmitted signals, and then the generated PIM may be transmitted back into an uplink receiver at the base station. The generation of PIM is by radio frequency mixing between, in this example, the two signals at frequencies f₁ and f₂, or between different frequency components of a modulated signal, such as an OFDM signal, which may be relatively wideband, occupying for example 10% or more of the passband of a frequency selective device. As a result of the radio frequency mixing, PIM product may be generated at various frequencies, but it is PIM products which fall at a frequency in a receive band of the cellular wireless system which may be problematic, since the PIM may be received as interference. PIM products generated by intermodulation within a wideband modulated signal may fall within or adjacent to the signal bandwidth and so may be seen as interference. For example, PIM products may be third order products appearing at frequencies 2 f₁-f₂ and 2 f₂-f₁. So, antenna array assemblies are typically tested on manufacture, and potentially also in the field, to determine whether they meet stringent specifications for the generation of PIM. In the event that an antenna array assembly is found to be generating PIM, it may be required to locate the source of PIM within the assembly, so that corrective action may be taken.

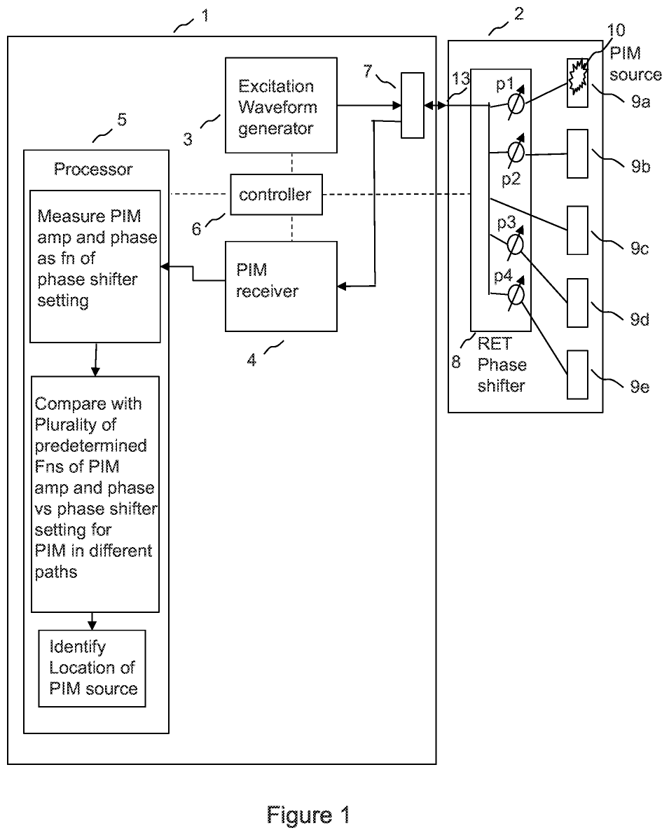

FIG. 1 shows test apparatus 1 in an embodiment of the invention for identifying a location of at least one PIM (passive intermodulation) source within an antenna array assembly 2. In the arrangement shown in FIG. 1, the antenna array assembly 2 is the device under test DUT), The antenna array assembly comprises a plurality of sub-arrays 9a-9e, a connection port 13, and a controllable multi-element phase shifter 8 configured to apply a respective phase shift to a respective path between the connection port 13 and each sub-array 9a-9e. The controllable multi-element phase shifter 8 is a device for applying a Remote Electrical Tilt (RET), which comprises a plurality of controllable phase shifting elements. Each sub-array may comprise one or more antenna elements for radiation and/or reception. The controllable multi-element phase shifter, which may also be referred to as a phase shifter or a RET phase shifter, may be implemented by various well known technologies to implement the function of providing an incremental phase shift across the sub-arrays, to provide adjustable tilt in the angle of the antenna beam. In an example, the controllable multi-element phase shifter may be a phase shifter having a power dividing function as described in US patent application US2006/0164185. A sliding arm pivots about an axis, and provides capacitive contact with several tracks, at a respective point along an arc on each track according to the angular setting of the sliding arm. This provides a power splitting function for power applied to the arm at the axis between tracks connected to the arc for connection to respective sub-arrays. The path length of the electrical signal path to a plurality of sub-arrays is adjusted by the position along the arc with which the arm makes electrical contact, and the path length sets the delay and so the transmission phase along each respective path. Arcs with a greater radius experience a greater delay and so a greater phase shift for a given angular setting of the sliding arm. Each angular setting of the arm, which may be referred to as a setting or a state of the multi-element phase shifter, will provide a predetermined phase shift for each path from the phase shifter to an antenna sub-array or element. Each state of the multi-element phase shifter may correspond to a RET tilt setting. The tilt setting may be controlled by an electric motor, under control of the test apparatus 1, controlled by a processor and/or controller in the test apparatus 1. There may be feedback from the RET control motor or tilt control mechanism of the tilt angle to the controller/processor of the test apparatus.

FIG. 1 shows the controllable multi-element phase shifter 8, which has at least 2 phase adjusting elements. In the example shown, the controllable multi-element phase shifter has a power splitting and combining function. In the example shown, there are 5 branches and 4 phase adjusting elements p2, p2, p3, p4. In this example, one branch is fed with a signal from the splitter/combiner that does not pass through a phase shifter so that it is invariant with the setting of the controllable multi-element phase shifter.

In the embodiment of the invention illustrated by FIG. 1, a signal generator, the excitation waveform generator 3, generates an excitation waveform to be applied via combiner 7, which may be for example a diplexer, coupler, or circulator to the connection port 13 of the device under test, in this case the antenna array assembly 2. The processor/controller of the test equipment sets the multi-element phase shifter to a first state to apply a respective phase shift to each of the respective paths, and makes a first measurement of at least the phase of a PIM product emitted from the connection port in response to the excitation waveform, as received in the receiver, i.e. the PIM receiver 4.

The processor/controller may then set the multi-element phase shifter to a succession of further states, the respective phase shift applied to each of the respective paths being dependent on the state, and make a further measurement of at least the phase of the PIM product emitted from the connection port for each of the further states. The processor/controller may then determine from the first and further measurements a dependence of at least the phase of the PIM product on the state of the multi-element phase shifter. The function representing the dependence of at least the phase of the PIM product on the state of the multi-element phase shifter may be referred to as a “cisoid”, which is a complex representation in inphase and quadrature components at baseband of the phase and/or amplitude of the received PIM product as a function of the phase shifter state, which may be expressed in terms of tilt angle.

The received PIM product may be a PIM product selected to be of interest for the test, typically a product of two or more signals or signal components in a downlink band for transmission by the antenna which fall within an uplink band of the antenna, and so would potentially appear as interference to received signals in use. The PIM receiver is accordingly tuned to receive the expected PIM product, for example a low side third order two tone product of the form f₁-2 f₂, where f₁ and f₂ are the respective carrier frequencies of the downlink band signals causing the PIM.

The determined dependence of at least the phase of the PIM product on the state of the multi-element phase shifter is then compared, under control of the controller/processor of the test apparatus, with a plurality of predetermined dependences of at least the phase of the PIM product on the state of the multi-element phase shifter, each predetermined dependence being for a PIM source located in a respective path between the multi-element phase shifter and a respective sub-array, including the respective sub-array. That is to say, the measured cisoid is compared with pre-determined cisoids for each path. The processor/controller then determines the location within the antenna array assembly of the at least one PIM source 10, shown in FIG. 1 for example in sub-array 9a, in dependence on the comparison. This allows identification of the signal path in which the PIM source is likely to be located, for example by identification of the path which corresponds to the pre-determined dependency or dependencies which best match the measured dependencies on RET setting, for example by cross-correlation or by linear least squares processing.

The signal processing circuit comprising a processor 5 as shown in FIG. 1, may be implemented using well known technology for implementing digital signal and control functions, for example as a programmable logic array, a digital signal processing chip, or the method may be performed in software, using program code held in memory and causing a processor to implement the method. The controller 6 shown in FIG. 1 may be part of the processor 5, and may perform scheduling and control functions.

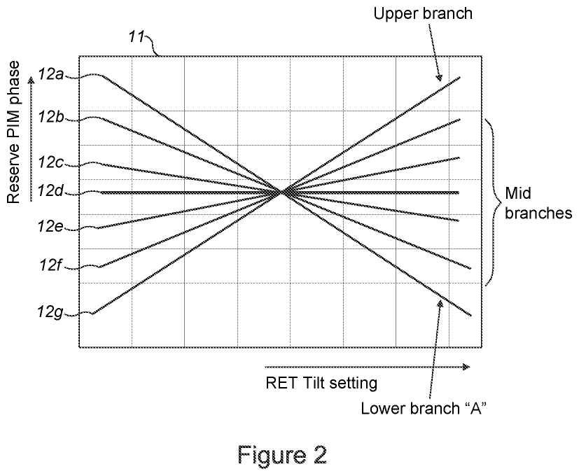

FIG. 2 shows examples of a plurality of predetermined dependences 12a-12g of at least the phase of the PIM product on the state, expressed as tilt angle, of the multi-element phase shifter, each predetermined dependence being for a PIM source located in a respective path between the multi-element phase shifter and a respective sub-array. It can be seen that the upper and lower branches have a steeper rate of change of phase with RET tilt setting than the mid branches. The vertical axis shows the phase of the PIM emitted from the connection port of the antenna array assembly, that is to say reverse PIM. The dependencies which are compared are relative phase between paths. It can be seen that in this example, one path, that is to say one branch, 12d, does not change with the RET tilt setting. This corresponds to a path, i.e. branch that is invariant with the setting of the phase shifter. The dependencies shown in FIG. 2 may be seen as representing the phase component of pre-determined cisoids.

The dependencies shown in FIG. 2 are for an idealised situation. In practice, the lines may not be straight, but may be curved and there may also be an amplitude as well as phase dependence on the setting of the RET phase shifter, due to the effects of reflections within the antenna array assembly and the effects of mutual coupling between sub-arrays. These effects produce multi-path effects that lead to constructive and destructive interference as a function of the setting, i.e. state, of the multi-element phase shifter. The predetermined dependencies may be determined in a way that takes into account the multi-path effects, by calculation and/or measurement.

The measures and pre-determined dependencies may be either of phase only or phase and amplitude representations of the PIM product. So, the first and the further measurements may be of the amplitude and phase of the PIM product, and the method comprises determining from the first and further measurements a dependence of the amplitude and phase of the PIM product on the state of the multi-element phase shifter. In this case the comparison process comprises comparing the determined dependence of the amplitude and phase of the PIM product on the state of the multi-element phase shifter with a plurality of predetermined dependences of the amplitude and phase of the PIM product on the state of the multi-element phase shifter, each predetermined dependence being for a PIM source located in a respective path between the multi-element phase shifter and a respective sub-array, including the respective sub-array. This may allow more accurate identification of the path in which the PIM source is likely to be located by taking into account amplitude as well as phase variation, which may result from imperfect impedance matching in the antenna array causing reflections.

Using a cross-correlation technique for the comparison of the measured and predetermined dependencies may be an efficient method of identifying which path a PIM source is likely to be located on, in particular in the case of a single PIM source.

Using a Linear Least Squares process for the comparison of the measured and predetermined dependencies may comprise identifying the location of one or more PIM sources by solution of Ax=b,
where:
A is a matrix of a plurality of predetermined dependences of the amplitude and phase of the PIM product on the state of the multi-element phase shifter, for PIM sources in different paths (whereby each path is represented by a different column of the matrix A);
b is a column vector representing the determined dependence of the measured amplitude and phase of the PIM product on the state of the multi-element phase shifter; and
x is a vector indicating the probability of PIM being located in each path, on the basis that x (once we have solved for it) represents the estimate of complex amplitude of the PIM located in each path. This provides an efficient method of identifying which path or paths a PIM source or sources are likely to be located on, particularly in the case of more than one PIM source.

The equation Ax=b may be solved for x by well-known linear algebra techniques. For example, the equation may be solved by matrix inversion or by Gaussian elimination and back substitution. The solution to the equation may be calculated by using signal processing chips, or by software running on a general purpose computer or by other digital signal processing hardware, software, and/or firmware.

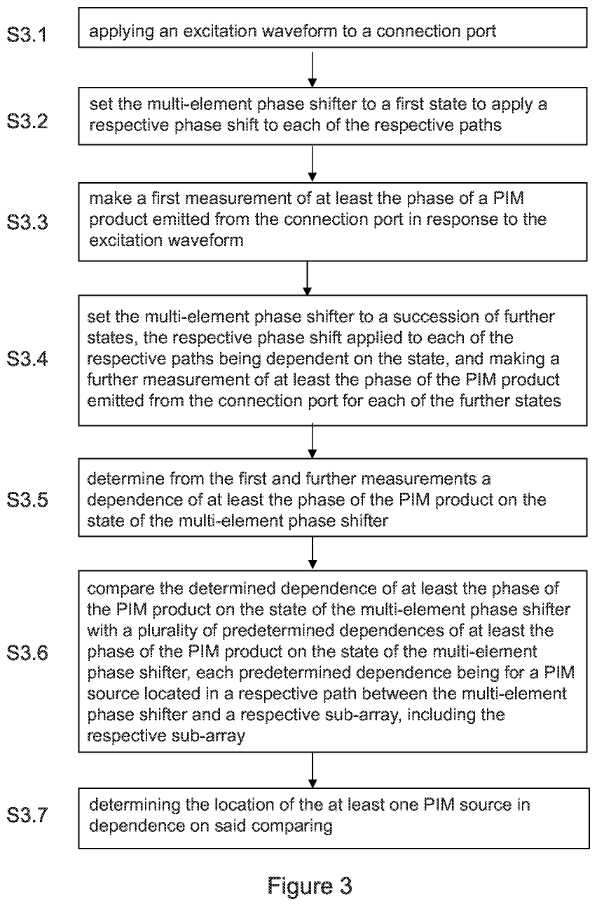

FIG. 3 is a flow chart showing a method of identifying a location of at least one PIM (passive intermodulation) source within an antenna array assembly in an embodiment of the invention, according to steps S3.1 to S3.7.

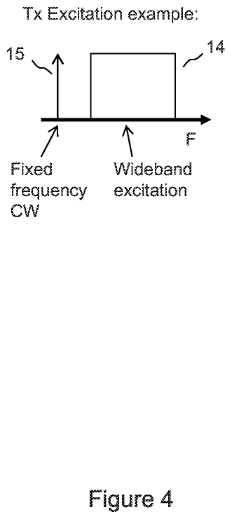

FIG. 4 shows an example of an excitation waveform in the frequency domain in an embodiment of the invention. In this example, the excitation waveform comprises a first 15 and a second 14 signal, wherein at least the first signal is a continuous wave (CW) signal, which provides a convenient way of implementing an excitation waveform. As shown in FIG. 4, the second signal may be a modulated signal, in which the modulation may be by a noise-like waveform having a bandwidth in the range 10 MHz to 40 MHz, which may provide improved resilience to phase distortion from reflections and element mutual coupling, and may facilitate delay measurements to determine range to a PIM source or sources as well as path. Alternatively, the second signal may a swept CW signal. This may be convenient if it is desired to measure the delay between the transmitted excitation signal and the received PIM signal, in order to estimate the location of the PIM source according to distance along a path.

In an alternative embodiment, the second signal may be a continuous wave (CW) signal. This provides a convenient way of implementing an excitation waveform for generating PIM of an expected frequency, and may conform to existing PIM test requirements.

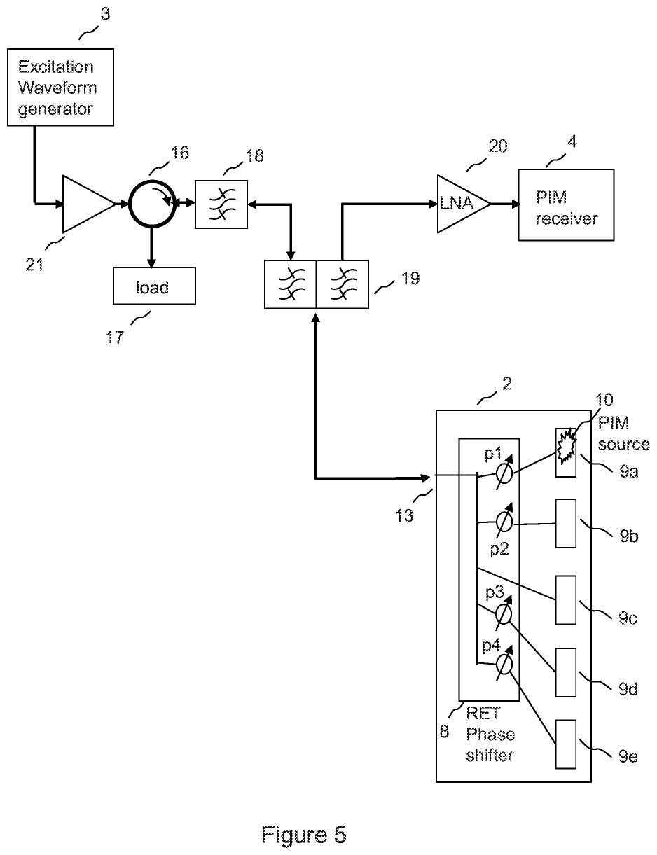

FIG. 5 shows an example of the implementation of the connection of the excitation waveform generator 3 and the PIM receiver 4 to the connection port of the antenna array assembly 2 under test in an embodiment of the invention. In this arrangement, the excitation waveform is generated in the excitation waveform generator 3, which may be a signal generator that generates the excitation waveform at digital baseband and upconverts it to the radio frequency specified for the test, typically a transmit frequency for the antenna array assembly, which will be a downlink frequency for the case of a base station antenna array assembly. In other applications, the transmit frequency may be an uplink frequency, or the terms uplink and downlink may not apply in some applications such as peer-to-peer networks. The excitation waveform at radio frequency is amplified by power amplifier 21, and then applied to circulator 16, which protects the power amplifier against reflected signals. Typically the amplified signal is filtered by a band pass filter 18 to remove spurious components and then applied to a diplexer 19, which routes signals at the transmit frequency to the connection port 13 of the antenna array assembly 2 with low loss, and also routes signal at receive frequencies from the connection port 13 of the antenna array assembly 2 to the low noise amplifier 20 and the PIM receiver. The PIM receiver is a radio receiver configured to receive the PIM product of interest at radio frequency and to typically downconvert it using conventional techniques to a digital baseband inphase and quadrature representation.

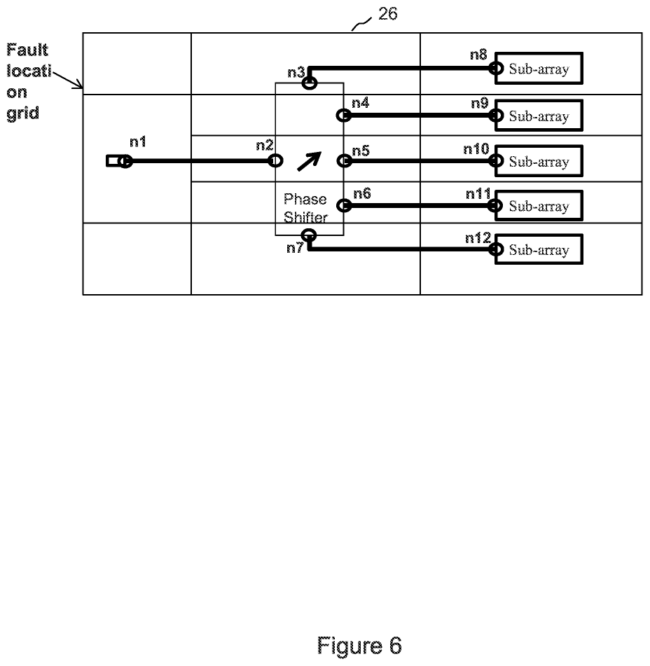

FIG. 6 illustrates a grid 26 for determining a location of a PIM source within an antenna array assembly using a combination of delay and path, i.e branch, location. As shown in FIG. 6, the location of a PIM source may be located to a point on a grid, on the basis of a determination of on which path the PIM is located, which gives the position on the vertical scale of FIG. 6, and on the basis of the distance from the connection port, which gives the position on the horizontal scale of FIG. 6. As can be seen, because the distances are relatively short, the resolution of any distance determination on the basis of delay is rather limited, but this may give a useful determination of whether the PIM source is likely to be located at the phase shifter, i.e. points n2-n7, at the sub-arrays, i.e. points n8-n12, or at the connection port n1. In the case that it is found that the best fit is a dependence characteristic in which the amplitude and phase are substantially invariant with the state of the RET phase shifter, the determination of delay may be used to determine whether the PIM is located before or after the phase shifter with respect to the connection port, for example whether the PIM source is at n1, n2/n5 or at n10 in FIG. 6. The delay of the PIM product may be determined by correlation of measured PIM with a replica of the PIM product. Alternatively, the delay may be determined by exciting the PIM source an excitation waveform in which one of the signals generating the PIM product is an FM CW signal. The delay may be found from the frequency of the received PIM product, given knowledge of the FM CW frequency as a function of time in the excitation waveform.

The location of at least one PIM source may be determined in dependence on the determined delay, based on a known relationship between delay and propagation distance for the transmission medium through which the signals propagate. The location can be described in combination with a path determined by comparing measured and pre-determined dependencies on the state of the phase shifter as already described.

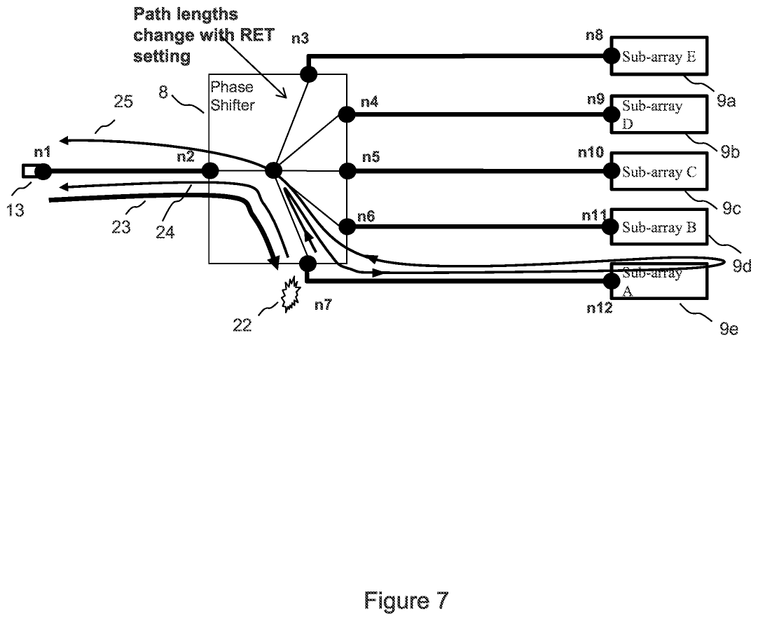

FIG. 7 shows an example of a reflective signal path 25 within an antenna array assembly. It can be seen in FIG. 7 that a PIM source 22 at n7 is excited by an excited waveform received along path 23. A PIM product is generated, and is transmitted along direct path 24 through the phase shifter 8 to the connection port 13. However, as shown, there may also be a reflection from an impedance mis-match in the phase shifter, causing a return signal to follow a path 25 to subarray A 9e, from which the PIM product is reflected and transmitted back to the connection port 13. This reflected signal will appear as a delayed multi-path component. There are also other possible routes for delayed signals, each with its own delay characteristics. For example, a PIM product reflected from within the phase shifter may be reflected back in a different path form the path by which it arrived, for example to n6 and subarray B 9d, from which it may then be transmitted back to the connection port 13. Also, there may be mutual coupling between the sub-arrays, so that, for example, a reflection back to n7 may enter sub-array a, be coupled to sub-array B, and then return to the connection port 13 via n6. It can be seen that many delayed multi-path routes are possible. These may be termed “phantom paths”, and each may be modelled to have its own pre-determined dependence of phase and/or amplitude as a function of the state of the multi-element phase shifter, for PIM sources on each of the paths, and potentially at various locations on each path. These pre-determined dependences for phantom paths may then be used for comparison with the measured dependency, for example by the linear least squares method. Matches between measured and predetermined dependencies can be used to determine on which path the PIM is located. This may be used in combination with other matches to increase the certainty of the location estimate, for example by building up a fingerprint of direct and phantom dependencies for each path.

So the plurality of predetermined dependences of at least the phase of the PIM product on the state of the multi-element phase shifter includes dependencies for reflective paths. This may allow the identification of reflective paths in addition to direct paths which may further assist in identifying a location or locations of sources of PIM.

Alternatively or in combination, a combined pre-determined dependency may be determined by combination of the direct and phantom dependencies for each setting of the phase shifter, and the combined dependency may be used for comparison with the measured dependency to determine on which path the PIM is located.

So, the plurality of predetermined dependences of at least the phase of the PIM product on the state of the multi-element phase shifter may include effects of mutual coupling between sub-arrays and may include effects of reflections between the phase shifter and the sub-arrays. This may allow more accurate identification of which path is causing PIM in the presence of reflections within the antenna array assembly.

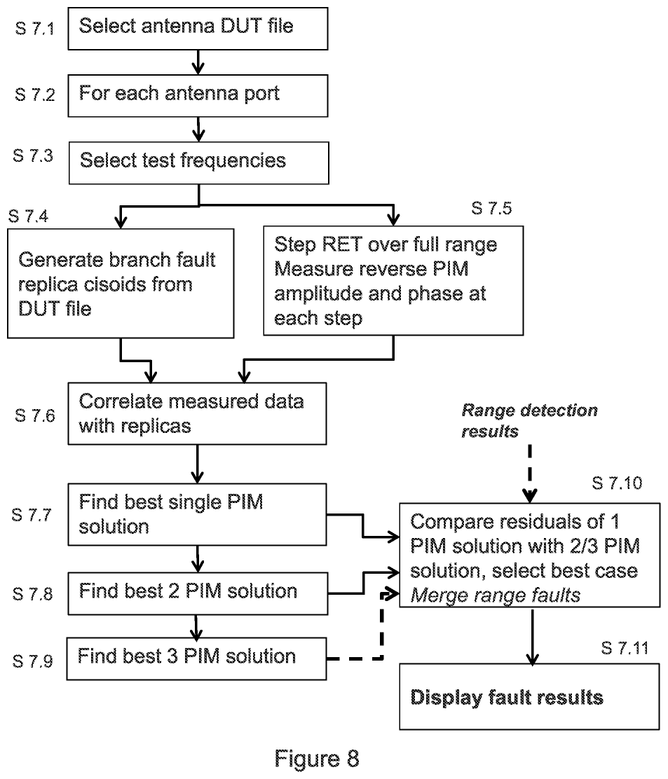

FIG. 8 is a flow chart showing a method of identifying and displaying a location of at least one PIM (passive intermodulation) source within a device under test (DUT) in an embodiment of the invention according to steps S7.1 to S7.11.

As shown in FIG. 8, in a test, there may be a predetermined file holding the predetermined results for the predetermined dependences of at least the phase of the PIM product on the state of the multi-element phase shifter, which may be referred to as replica cisoids. These files and the required carrier frequencies for the test are retrieved form memory and used to set up the test apparatus to test the antenna array assembly which is the device under test. The RET, i.e. the controllable multi-element phase shifter is then set to various states, in this example being stepped over its full range. The measured dependencies on RET setting are compared with the pre-determined dependencies. In this example the comparison is by correlation. The comparison may alternatively be by a linear least squares process. Comparisons are made assuming one PIM source and picking the best predetermined candidate dependency, and then assuming 2 and/or 3 PIM sources and picking the best 2 and 3 candidates respectively. The residual is calculated on the basis of the difference between the measured and predetermined dependencies. The solution with the least difference is selected as the most likely path or paths. The fault result is displayed, comprising the most likely paths and optionally the position along the path, according to range detection results on the basis of a measure of delay as already mentioned.

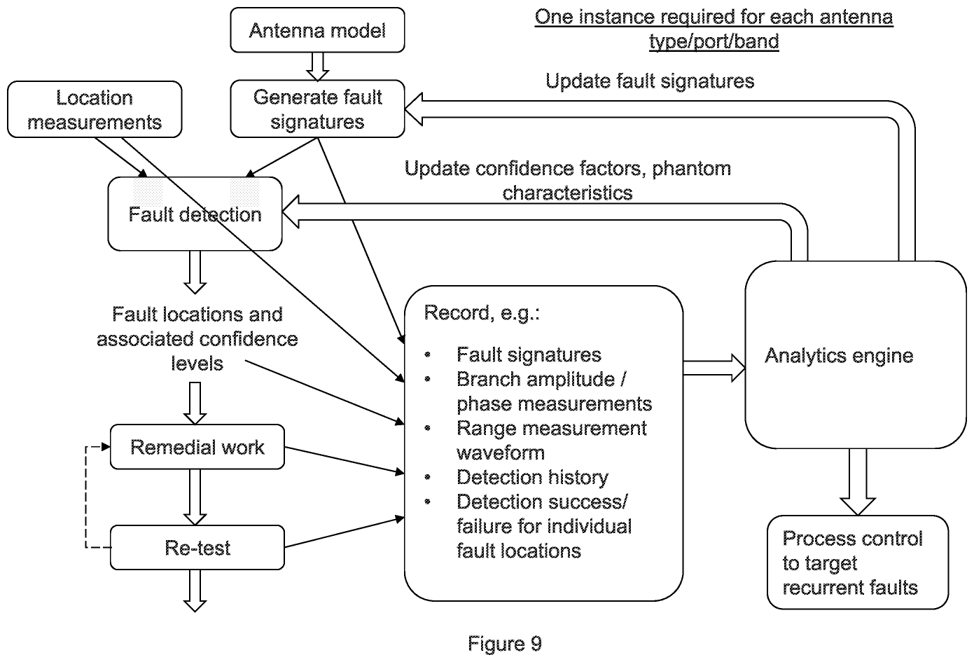

FIG. 9 is a flow diagram illustrating a process flow for analytics of PIM location. This method can add capability to provide more robust fault detection than a basic detection method based solely on fault signatures based on the high level antenna model. The high level antenna model is used to generate fault signatures for the various fault locations. Typically these consist of range to fault locations for each fault node as well as cisoid frequencies for each branch, the cisoid frequencies representing the dependence of at least the phase of the PIM product on the state of the multi-element phase shifter.

Measurements are made of the complex reverse PIM response vs tilt angle and a wideband reverse PIM response obtained. The detection process is then run which compares the measurements with the candidate fault location signatures. The output of this process are the likely fault locations, levels and confidence metrics. The latter is an indication of how closely the measurements correspond with the detected fault locations. Remedial action is then taken to repair the faulty locations and the antenna re-tested to confirm if the repair has been successful, then this loop may need to be repeated.

A range of data may be collected during the overall process and this data used to improve the overall detection reliability by tuning it on the basis of the success and failure of the detections as the available result history is built up over multiple antenna testings. For example it may be found over time that the fault signatures are not closely matching the measured results. For the example of single detected faults, corresponding to actual faults identified at locations known by their successful repair, the fault signatures may be updated so as to more accurately match the measured data.

Secondly the reliability of certain detections can be monitored by examining the repair success and the detection confidence process tuned to more accurately reflect the measured detection probability and false alarm rates. It is possible that certain fault locations may also generate a spurious or phantom detection at a second location. Over multiple antenna measurements and corresponding good or bad detections it will become clearer where these phantom detections are likely to occur and the corresponding detection confidence levels modified accordingly. A further benefit of this process is that the frequency of individual fault conditions may be monitored and a high occurrence of specific faults may then be investigated to ascertain if a certain manufacturing process is at fault and corrective action taken to remedy this

It may already be known from the antenna design that certain fault locations are likely to occur more often. For example certain sections of the feed network are likely to have more solder joints and or be subject to greater RF power and hence be more likely to exhibit a greater propensity to fault conditions.

The detection confidence process may be pre-primed to take advantage of this using, for example, Bayesian statistics. In addition to the historical learning process outlined on the previous chart a fast learning mode could be of benefit in accelerating the process. One way this may be accomplished is by taking a known good antenna and then introducing faults node by node and updating the corresponding fault signatures to better match the measured data.

The above embodiments are to be understood as illustrative examples of the invention. It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

1. A method of identifying a location of at least one PIM (passive intermodulation) source within an antenna array assembly comprising a plurality of sub-arrays, a connection port, and a controllable multi-element phase shifter configured to apply a respective phase shift to a respective path between the connection port and each sub-array, the method comprising:
applying an excitation waveform to the connection port;
setting the multi-element phase shifter to a first state to apply a respective phase shift to each of the respective paths;
making a first measurement of at least the phase of a PIM product emitted from the connection port in response to the excitation waveform;
setting the multi-element phase shifter to a succession of further states, the respective phase shift applied to each of the respective paths being dependent on the state, and making a further measurement of at least the phase of the PIM product emitted from the connection port for each of the further states;
determining from the first and further measurements a dependence of at least the phase of the PIM product on the state of the multi-element phase shifter;
comparing the determined dependence of at least the phase of the PIM product on the state of the multi-element phase shifter with a plurality of predetermined dependences of at least the phase of the PIM product on the state of the multi-element phase shifter, each predetermined dependence being for a PIM source located in a respective path between the multi-element phase shifter and a respective sub-array, including the respective sub-array; and
determining the location within the antenna array assembly of the at least one PIM source in dependence on said comparing.

2. The method of claim 1, wherein the first and the further measurements are of the amplitude and phase of the PIM product, and the method comprises determining from the first and further measurements a dependence of the amplitude and phase of the PIM product on the state of the multi-element phase shifter, and said comparing comprises:
comparing the determined dependence of the amplitude and phase of the PIM product on the state of the multi-element phase shifter with a plurality of predetermined dependences of the amplitude and phase of the PIM product on the state of the multi-element phase shifter, each predetermined dependence being for a PIM source located in a respective path between the multi-element phase shifter and a respective sub-array, including the respective sub-array.

3. The method of claim 1, wherein said comparing comprises a cross-correlation

4. The method of claim 1, wherein said comparing comprises a Linear Least Squares process.

5. The method of claim 4, comprising identifying the location of one or more PIM sources by solution of Ax=b,
where:
A is a matrix of a plurality of predetermined dependences of the amplitude and phase of the PIM product on the state of the multi-element phase shifter, for PIM sources in different paths;
b is a column vector representing the determined dependence of the measured amplitude and phase of the PIM product on the state of the multi-element phase shifter; and
x is a vector indicating the probability of PIM being located in each path.

6. The method of claim 1, wherein the controllable multi-element phase shifter is a device for applying a Remote Electrical Tilt (RET).

7. The method of claim 1, wherein the controllable multi-element phase shifter comprises a plurality of power dividers and a plurality of controllable phase shifting elements.

8. The method of claim 1, wherein each sub-array comprises one or more antenna elements for radiation and/or reception.

9. The method of claim 1, wherein the excitation waveform comprises a first and a second signal, wherein at least the first signal is a continuous wave (CW) signal.

10. The method of claim 9, wherein the second signal is a continuous wave (CW) signal.

11. The method of claim 9, wherein the second signal is a modulated signal.

12. The method of claim 11, wherein the second signal is modulated with a noise-like waveform having a bandwidth in the range 10 MHz to 40 MHz.

13. The method of claim 11, comprising:
determining a delay of the PIM product by correlation of measured PIM with a replica of the PIM product; and
determining the location of the at least one PIM source in dependence on the determined delay in combination with a path determined by said comparing.

14. The method of claim 1, wherein the plurality of predetermined dependences of at least the phase of the PIM product on the state of the multi-element phase shifter include effects of mutual coupling between sub-arrays.

15. The method of claim 1, wherein the plurality of predetermined dependences of at least the phase of the PIM product on the state of the multi-element phase shifter include effects of reflections between the phase shifter and the sub-arrays.

16. The method of claim 1, wherein the plurality of predetermined dependences of at least the phase of the PIM product on the state of the multi-element phase shifter includes dependencies for reflective paths.

17. The method of claim 1, wherein each state of the phase shifter represents a tilt angle for the antenna array.

18. Test apparatus for identifying a location of at least one PIM (passive intermodulation) source in an antenna array assembly comprising a plurality of sub-arrays, a connection port, and a controllable multi-element phase shifter configured to apply a respective phase shift to a respective path between the connection port and each sub-array, the test apparatus comprising:
a signal generator configured to generate an excitation waveform for application to the connection port;
a receiver configured to receive a PIM product emitted from the connection port in response to the excitation waveform; and
a circuit comprising a processor configured to:
set the multi-element phase shifter to a first state to apply a respective phase shift to each of the respective paths;
make a first measurement of at least the phase of a PIM product emitted from the connection port in response to the excitation waveform;
set the multi-element phase shifter to a succession of further states, the respective phase shift applied to each of the respective paths being dependent on the state, and making a further measurement of at least the phase of the PIM product emitted from the connection port for each of the further states;
determine from the first and further measurements a dependence of at least the phase of the PIM product on the state of the multi-element phase shifter; and
comparing the determined dependence of at least the phase of the PIM product on the state of the multi-element phase shifter with a plurality of predetermined dependences of at least the phase of the PIM product on the state of the multi-element phase shifter, each predetermined dependence being for a PIM source located in a respective path between the multi-element phase shifter and a respective sub-array, including the respective sub-array; and
determine the location within the antenna array assembly of the at least one PIM source in dependence on said comparing.
